(19) United States
(12) Patent Application Publication
(10) Pub. No.: US 2026/0096298 A1
(43) Pub. Date: Apr. 2, 2026

(54) LIGHT-EMITTING SUBSTRATE, DISPLAY PANEL, AND METHOD FOR MANUFACTURING THE SAME

(71) Applicant: HKC CORPORATION LIMITED, SHENZHEN (CN)

(72) Inventors: Yao LI, SHENZHEN (CN); Pei XU, SHENZHEN (CN)

(73) Assignee: HKC CORPORATION LIMITED, SHENZHEN (CN)

(21) Appl. No.: 19/336,255

(22) Filed: Sep. 22, 2025

(30) Foreign Application Priority Data
Sep. 30, 2024 (CN) 202411400021.2

(51) Int. Cl. H10K 59/122; H10K 59/12; H10K 59/131

(52) U.S. Cl. CPC H10K 59/122; H10K 59/1201; H10K 59/131

(57) ABSTRACT

A light-emitting substrate, a display panel, and a manufacturing method of the same. The light-emitting substrate includes a glass substrate, defining first glass through holes, where at least two conductive portions are arranged in each first glass through hole, and the at least two conductive portions in the first glass through hole are insulated from each other; a metal pattern layer, disposed on the glass substrate and including anodes and connecting lines; where each conductive portion is electrically connected to a corresponding anode via a corresponding connecting line; a light-emitting layer, including light-emitting structures; where each light-emitting structure is disposed on a corresponding anode; and a cathode, disposed on a side of the light-emitting structures away from the glass substrate; where the cathode, the light-emitting structures, and the anodes together form light-emitting units.

### CROSS-REFERENCE TO RELATED APPLICATIONS

The present application claims priority of Chinese Patent Application No. 202411400021.2, filed on Sep. 30, 2024, the entire contents of which are hereby incorporated by reference in their entirety.

### TECHNICAL FIELD

The present disclosure relates to the field of display technologies, and in particular to a light-emitting substrate, a display panel, and a method for manufacturing the same.

### BACKGROUND

A single-crystal silicon drive backplate is a drive substrate formed by semiconductor devices fabricated through Complementary Metal Oxide Semiconductor (CMOS) processes as driving units. Compared to conventional Active-matrix organic light-emitting diode (AMOLED) panels that utilize amorphous silicon, microcrystalline silicon, or low-temperature polycrystalline silicon thin-film transistors as backplates, the single-crystal silicon drive backplate demonstrates significantly higher carrier mobility. Consequently, Silicon-based Organic Light-Emitting Diode (SiOLED) display panels are currently the highest-performance display technology applied in AR/VR products.

Currently, the silicon-based OLED display panel integrates the conventional externally-bonded display chip into the silicon-based drive backplate. The fabrication method thereof involves vapor-depositing OLED light-emitting devices onto a silicon-based drive substrate. Specifically, this process includes: depositing to form an anode; forming a pixel definition layer; and sequentially, depositing an organic emissive layer and a cathode. This approach enables the production of subpixels with smaller dimensions, thereby achieving display fineness exceeding retinal resolution, further with advantages such as high resolution, high integration density, low power consumption, compact size, and lightweight structure.

However, directly vapor-depositing OLED emissive devices onto the silicon-based drive substrate may easily affect the silicon-based drive circuits, causing damage to the drive circuits and rendering them unusable, thereby increasing costs.

### SUMMARY OF THE DISCLOSURE

The present disclosure provides a light-emitting substrate, including:
a glass substrate, defining a plurality of first glass through holes; wherein at least two conductive portions are arranged in each first glass through hole, and the at least two conductive portions in the first glass through hole are insulated from each other;
a metal pattern layer, disposed on the glass substrate and including a plurality of anodes and a plurality of connecting lines; wherein each conductive portion is electrically connected to a corresponding anode via a corresponding connecting line;
a light-emitting layer, including a plurality of light-emitting structures; wherein each light-emitting structure is disposed on a corresponding anode; and
a cathode, disposed on a side of the plurality of light-emitting structures away from the glass substrate; wherein the cathode, the plurality of light-emitting structures, and the plurality of anodes together form a plurality of light-emitting units.

The present disclosure further provides a display panel, including:
the light-emitting substrate as above; and
a drive substrate, including a drive circuit layer and drive electrodes arranged on a side of the drive circuit layer; wherein the drive substrate is aligned with the light-emitting substrate, and the drive electrodes are aligned and connected with the at least two conductive portions in each first glass through hole in a one-to-one correspondence.

The present disclosure further provides a method for manufacturing a display panel, including:
preparing a drive substrate; wherein the drive substrate includes a drive circuit layer and drive electrodes arranged on a side of the drive circuit layer;
preparing a light-emitting substrate, including:
   providing a glass substrate, and defining a plurality of glass through holes on the glass substrate;
   preparing at least two conductive portions in each glass through hole, wherein the at least two conductive portions in the glass through hole are insulated from each other;
   preparing a metal pattern layer on the glass substrate to form a plurality of anodes and a plurality of connecting lines; wherein one of two ends of each connecting line is connected to a corresponding anode, and the other of the two ends of the connecting line is connected to a corresponding conductive portion;
   preparing a light-emitting layer on the metal pattern layer to form a plurality of light-emitting structures; wherein each light-emitting structure is disposed on a corresponding anode; and
   preparing a cathode on the plurality of light-emitting structures to form a plurality of light-emitting units; wherein each light-emitting unit includes the cathode, a corresponding light-emitting structure, and a corresponding anode; and
aligning and connecting the drive substrate with the light-emitting substrate to form an electrical connection between each drive electrode and a corresponding conductive portion.

### BRIEF DESCRIPTION OF THE DRAWINGS

To more clearly illustrate the technical solutions of the embodiments of the present disclosure, the following is a brief introduction to the drawings used in the description of the embodiments. It should be understood that the drawings described below are merely some embodiments of the present disclosure. For those skilled in the art, other drawings can be obtained without any creative effort based on these drawings.

FIG. 1 is a structural schematic view of a light-emitting substrate according to a first implementation of the present disclosure.

FIG. 2 is a structural schematic view of a light-emitting substrate according to a second implementation of the present disclosure.

FIG. 3 is a top structural schematic view of a glass through hole as shown in FIG. 2.

FIG. 4 is a top structural schematic view of a light-emitting unit and a glass through hole according to a first implementation of the present disclosure.

FIG. 5 is a top structural schematic view of a light-emitting unit and a glass through hole according to a second implementation of the present disclosure.

FIG. 6 is top structural schematic view of a light-emitting unit and a glass through hole according to a third implementation of the present disclosure.

FIG. 7 is a structural schematic view of a light-emitting substrate according to a third implementation of the present disclosure.

FIG. 8 is a structural schematic view of a display panel according to some embodiments of the present disclosure.

FIG. 9 is a flowchart of a method for manufacturing a display panel according to some embodiments of the present disclosure.

FIG. 10 is a flowchart of a method for manufacturing a light-emitting substrate according to some embodiments of the present disclosure.

FIG. 11 is a flowchart of operation S22 in FIG. 10 according to some embodiments of the present disclosure.

FIG. 12 is a schematic view of the process corresponding to FIG. 11.

FIG. 13 is a flowchart of operation S22 in FIG. 10 according to other embodiments of the present disclosure.

FIG. 14 is a schematic view of the process corresponding to FIG. 13.

FIG. 15 is a flowchart of operation S23 in FIG. 10 according to some embodiments of the present disclosure.

FIG. 16 is a schematic view of the process corresponding to FIG. 15.

FIG. 17 is a flowchart of operations S24 and S25 in FIG. 10 according to some embodiments of the present disclosure.

FIG. 18 is a schematic view of the process corresponding to FIG. 17.

### DETAILED DESCRIPTION

The following description, in conjunction with the accompanying drawings, provides a detailed explanation of the technical solutions of the embodiments of the present disclosure.

In the following description, specific details such as specific system structures, interfaces, and technologies are provided for the purpose of explanation rather than limitation, in order to facilitate a thorough understanding of the present disclosure.

The technical solutions in the embodiments of the present disclosure will be described in detail with reference to the accompanying drawings. It should be noted that the embodiments described herein are only some of the embodiments of the present disclosure and are not intended to be exhaustive. All other embodiments obtained by those skilled in the art without making creative contributions based on the embodiments of the present disclosure are within the scope of the present disclosure.

The terms “first,” “second,” and “third” used in the present disclosure are for descriptive purposes only and should not be understood as indicating or implying relative importance or the number of technical features indicated. Therefore, features defined with “first,” “second,” or “third” may explicitly or implicitly include at least one of the features indicated. In the description of the present disclosure, “multiple” means at least two, such as two, three, etc., unless otherwise explicitly specified. All directional indications (such as up, down, left, right, front, back, etc.) in the embodiments of the present disclosure are intended solely to explain relative positions and movements of components in a specific orientation (as shown in the drawings). When the specific orientation changes, the directional indications also change accordingly. Furthermore, the terms “include” and “have,” as well as any variations thereof, are intended to cover non-exclusive inclusion. For example, a process, method, system, product, or device that includes a series of steps or units is not limited to the steps or units listed, but may optionally include steps or units not listed, or may optionally include other steps or units inherent to such process, method, product, or device.

The term “embodiment” as used herein means that the specific features, structures, or characteristics described in connection with an embodiment may be included in at least one embodiment of the present disclosure. The appearance of this term at various locations in the specification does not necessarily refer to the same embodiment, nor does it indicate that the embodiments are mutually exclusive or independent alternatives. Those skilled in the art will understand that the embodiments described herein may be combined with other embodiments.

The present disclosure will be described in detail with reference to the accompanying drawings and embodiments.

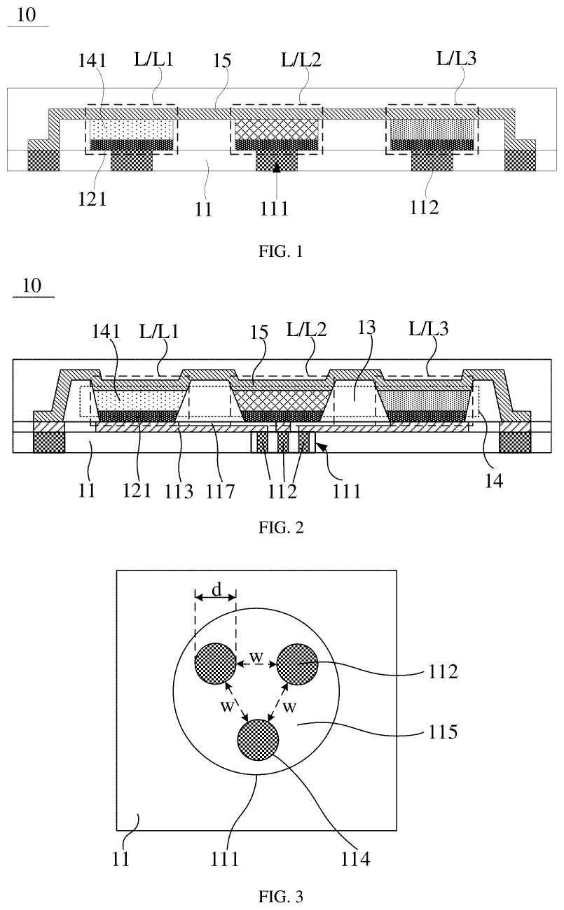

Referring to FIG. 1, FIG. 1 is a structural schematic view of a light-emitting substrate according to a first implementation of the present disclosure. In the embodiments, a light-emitting substrate 10 is provided, which includes a glass substrate 11, multiple light-emitting units L, and multiple conductive portions 112.

The glass substrate 11 includes a first side and a second side that are opposite to each other. Each light-emitting unit L is disposed on the first side of the glass substrate 11 and includes an anode 121, a light-emitting structure 141, and a cathode 15 that are stacked on the glass substrate 11. The cathodes 15 of the multiple light-emitting units L are interconnected and extend to an edge region of the glass substrate 11 to be connected to a cathode power supply signal, thereby ensuring that the cathode voltage of each light-emitting unit L is the same. In some embodiments, the light-emitting unit L may include a first light-emitting unit L1, a second light-emitting unit L2, and a third light-emitting unit L3 with different light-emitting colors, such as a red light-emitting unit L, a green light-emitting unit L, and a blue light-emitting unit L, respectively, to achieve color display. Specifically, the light-emitting color of the light-emitting unit L is determined by the light-emitting color of the light-emitting structure 141. Alternatively, in other embodiments, the light-emitting units L may be light-emitting units L of the same color, such as white, red, green, blue, or other colors, which may be set according to actual needs. For example, the light-emitting units L are white, and grayscale display is achieved by controlling the brightness of the light-emitting units L. Additionally, a color-blocking layer may be added above the light-emitting units L to achieve color display.

The glass substrate 11 defines multiple glass through holes 111, and the conductive portions 112 are disposed within the glass through holes 111 in a one-to-one correspondence and electrically connected to the anodes 121 in a one-to-one correspondence; the glass through hole 111 in the edge region of the glass substrate 11 is disposed in correspondence with and facing the cathode 15 extending to the edge region, and the conductive portion 112 disposed within the glass through hole 111 is electrically connected to the cathode 15.

The light-emitting substrate 10 can be aligned and connected with the drive substrate 20 such that drive electrodes 23 on the drive substrate 20 are aligned and connected with the conductive portions 112 in a one-to-one correspondence, thereby enabling drive signals from the drive substrate 20 to be transmitted through the drive electrodes 23 and the conductive portions 112 to the light-emitting units L, and thus driving the light-emitting units L to emit light and achieve image display.

Through the above configuration, the light-emitting substrate 10 is electrically coupled to the drive substrate 20 via alignment and connecting, thereby enabling the light-emitting unit array to be formed on the glass substrate 11. This allows the light-emitting units L to be fabricated on the glass substrate 11 rather than directly on the drive substrate 20, avoiding damage to the pixel drive circuit caused by directly forming the light-emitting units L on the drive substrate 20, which would reduce product yield. Additionally, by using the glass substrate 11 as a substrate for the light-emitting substrate 10, compared to a silicon-based substrate, the glass substrate 11 has excellent insulating properties, so there is no need to form an oxide insulating layer on walls of the glass through holes 111, nor is specialized thin wafer handling technology required, thereby reducing costs. Furthermore, the glass substrate 11 is less expensive than the silicon substrate 21, further lowering costs. In addition, due to the excellent insulating properties of the glass substrate 11, electromagnetic coupling effects are minimized during signal transmission, effectively reducing signal insertion loss and crosstalk, thereby ensuring signal integrity. Furthermore, by fabricating the light-emitting units L on the glass substrate 11, it is advantageous to achieve a large-sized light-emitting substrate 10.

In the above-mentioned light-emitting substrate 10, the glass through holes 111 and the conductive portions 112 are in a one-to-one correspondence, i.e., one conductive portion 112 is provided within each glass through hole 111 to transmit one signal. However, for ultra-high PPI light-emitting substrates 10, such as when PPI exceeds 3000, in a case where the size of a single light-emitting unit L is approximately 5 μm or smaller, and each anode 121 corresponds to a single glass through hole 111, the number of glass through holes 111 on the glass substrate 11 increases significantly, resulting in an extremely high density of glass through holes 111. This poses significant challenges for the drilling process and the stability of the glass substrate 11. Therefore, for the ultra-high PPI display panel 100, the one-to-one correspondence between the anodes 121 and the glass through holes 111 is no longer sufficient to meet the requirements. To address this technical issue, the present disclosure further proposes the following technical solution.

Referring to FIG. 2, FIG. 2 is a structural schematic view of a light-emitting substrate according to a second implementation of the present disclosure. In the embodiments, a light-emitting substrate 10 is provided, which includes a glass substrate 11, a metal pattern layer, a light-emitting layer 14, and a cathode 15.

The glass substrate 11 defines multiple glass through holes 111, with at least two conductive portions 112 arranged in each glass through hole 111, and the at least two conductive portions 112 in the glass through hole 111 are insulated from each other. The metal pattern layer is disposed on the glass substrate 11 and includes multiple anodes 121 and connecting lines 113; each conductive portion 112 is electrically connected to a corresponding anode 121 via a corresponding connecting line 113. The light-emitting layer 14 includes multiple light-emitting structures 141 each disposed on a corresponding anode 121, and the light-emitting structures 141 are each in contact with a corresponding anode 121. The cathode 15 is disposed on a side of the light-emitting structures 141 away from the glass substrate 11 and is in contact with the light-emitting structures 141; the cathode 15, together with a corresponding set of the light-emitting structure 141 and anode 121, forms a corresponding light-emitting unit L.

In the embodiments, by providing at least two mutually insulated conductive portions 112 in the glass through hole 111 and forming connecting lines 113 on the metal pattern layer, each conductive portion 112 in the glass through hole 111 can be electrically connected to a corresponding anode 121 via the connecting lines 113. i.e., a single glass through hole 111 can correspond to at least two anodes 121, and multiple signals can be transmitted within a single glass through hole 111. This configuration may reduce the number of glass through holes 111 by at least half, thereby reducing the density of glass through holes 111 on the glass substrate 11 by at least half, which effectively reduces the number of glass through holes 111 on the glass substrate 11 and the density of glass through holes 111 on the glass substrate 11, meeting the requirements of the drilling process, thereby improving the drilling yield and enhancing the strength of the glass substrate 11. Additionally, by incorporating at least two conductive portions 112 within the glass through hole 111, the drilling density of the glass substrate 11 is reduced, while also meeting the design requirements for ultra-high resolution, thereby achieving ultra-high resolution for the display panel 100 and enhancing image display quality.

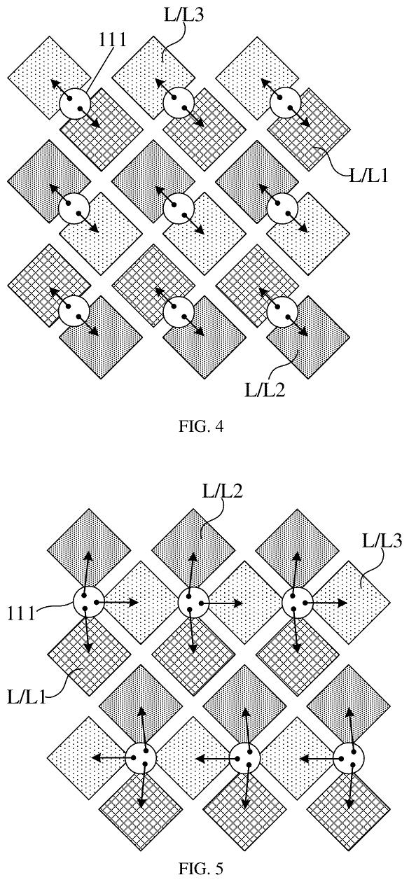

Referring to FIG. 3, FIG. 3 is a top structural schematic view of a glass through hole as shown in FIG. 2. Specifically, the glass through hole 111 is filled with an insulating limiting layer 115, and the insulating limiting layer 115 defines at least two electrode through holes 114, with the conductive portion 112 filled and disposed within a corresponding one of the electrode through holes 114. The material of the insulating limiting layer 115 may be an organic insulating material, such as polyvinyl chloride (PVC), polypropylene (PP), or other organic insulating materials. Specifically, the electrode through hole 114 may be prepared by nanoimprinting in the insulating limiting layer 115, and then the electrode through hole 114 may be filled with conductive material to form the conductive portion 112.

By providing the insulating limiting layer 115 in the glass through hole 111, the conductive portion 112 is fixed and limited, preventing signal transmission failures caused by the conductive portion 112 shifting or breaking. In addition, the conductive portions 112 in the glass through hole 111 are mutually insulated, preventing signal short-circuiting issues.

Specifically, the diameter of the electrode through hole 114 may be set based on the diameter of the glass through hole 111 and the number of the conductive portions 112 within the glass through hole 111. To ensure signal transmission stability, the diameter d of the electrode through hole 114 is typically set to be greater than 0.2 μm, and the spacing w between adjacent electrode through holes 114 shall be maintained at 0.2 μm or greater. In some embodiments, the number of the electrode through holes 114 in each glass through hole 111 may be determined based on the size of the light-emitting unit L and the diameter of the glass through hole 111, and then the diameter d of the electrode through hole 114 may be determined. Considering the stability of signal transmission, the diameter d of the electrode through hole 114 shall be as large as possible to ensure the stability of signal transmission. Therefore, the diameter d of the electrode through hole 114 may be made as large as possible while meeting the requirements for the number and diameter of the glass through holes 111.

Furthermore, after determining the opening positions of the glass through holes 111 on the glass substrate 11, wiring is performed on the glass substrate 11 to form the connecting lines 113, which route the signals from the anodes 121 of the surrounding light-emitting units L to the corresponding through hole positions and electrically connect the anodes 121 to the corresponding conductive portions 112.

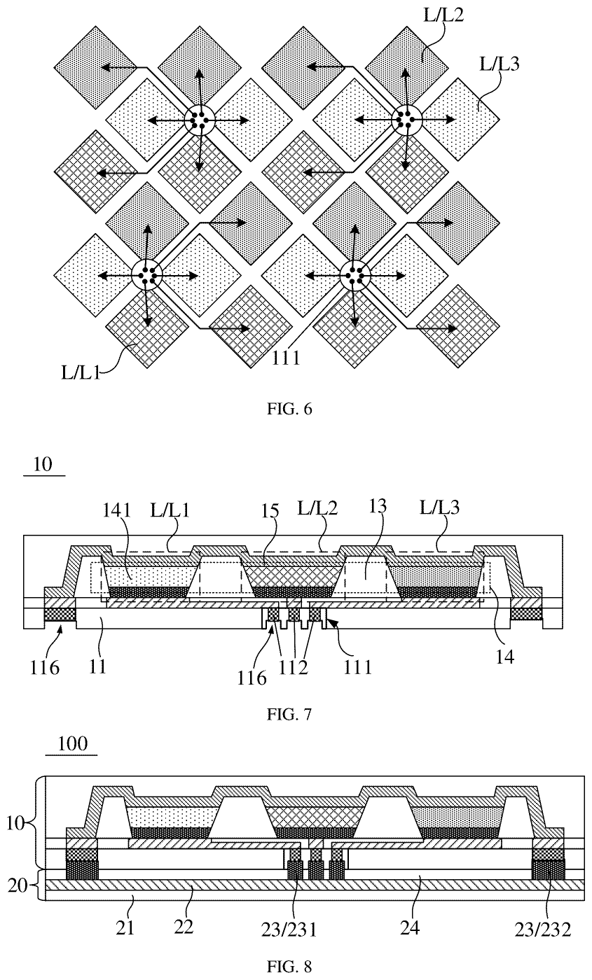

Specifically, the number of the conductive portions 112 in each glass through hole 111 may be set according to the above implementations. The glass through holes 111 may be defines between multiple adjacent light-emitting units L, and the at least two conductive portions 112 in each glass through hole 111 are electrically connected to the anodes 121 of adjacent light-emitting units L. For example, reference may be made to the embodiments shown in FIGS. 4-6 below.

Referring to FIG. 4, FIG. 4 is a top structural schematic view of a light-emitting unit and a glass through hole according to a first implementation of the present disclosure. In the embodiments, the glass through hole 111 is disposed between adjacent two light-emitting units L. Two conductive portions 112 are provided within the glass through hole 111, and the two conductive portions 112 are electrically connected to the anodes 121 of the two adjacent light-emitting units L via connecting lines 113. That is, the anodes 121 of the adjacent two light-emitting units L share a single glass through hole 111 and are electrically connected to the corresponding conductive portions 112 within the glass through hole 111. In other embodiments, the glass through hole 111 may be disposed below one of the adjacent light-emitting units L. In this case, the anode 121 of the light-emitting unit L is directly electrically connected to the corresponding conductive portion 112, while the anode 121 of the other light-emitting unit L is electrically connected to the corresponding conductive portion 112 via a connecting line 113. The specific position of the glass through hole 111 may be set according to actual needs. Through the above configuration, the two anodes 121 share a single glass through hole 111, thereby reducing the number of glass through holes 111 by half and lowering the density of glass through holes 111 on the glass substrate 11 by half.

Referring to FIG. 5, FIG. 5 is a top structural schematic view of a light-emitting unit and a glass through hole according to a second implementation of the present disclosure. In the embodiments, the glass through hole 111 is disposed at an intersection of three adjacent light-emitting units L. Three conductive portions 112 are provided within the glass through hole 111, and each of the three conductive portions 112 is electrically connected to a corresponding anode 121 of the adjacent three light-emitting units L via a connecting line 113. That is, the anodes 121 of the three adjacent light-emitting units L share a single glass through hole 111 and are electrically connected to the corresponding conductive portions 112 within the glass through hole 111. In other embodiments, the glass through hole 111 may be disposed below one of the three adjacent light-emitting units L, such as the middle light-emitting unit L. The anode 121 of the light-emitting unit L may be directly electrically connected to the corresponding anode 121, and the anodes 121 of the other two light-emitting units L are respectively electrically connected to the corresponding conductive portion 112 through connecting lines 113. The specific position of the glass through hole 111 may be set according to actual needs. Through the above configuration, the three anodes 121 share a single glass through hole 111, reducing the number of glass through holes 111 by two-thirds and lowering their density on the glass substrate 11 by two-thirds, thereby effectively reducing the number of through holes and their density, and thus improving the through hole yield and the strength of the glass substrate 11.

Referring to FIG. 6, FIG. 6 is top structural schematic view of a light-emitting unit and a glass through hole according to a third implementation of the present disclosure. In the embodiments, the glass through hole 111 is disposed at an intersection of four adjacent light-emitting units L. Six conductive portions 112 are provided within the glass through hole 111, with four of the conductive portions 112 respectively connected to the anodes 121 of the four adjacent light-emitting units L via connecting lines 113 to achieve electrical connection. Another two light-emitting units L are adjacent to the four adjacent light-emitting units L. The anodes 121 of these two light-emitting units L are respectively electrically connected to the other two conductive portions 112 in the glass through hole 111 via connecting lines 113. That is, the six adjacent anodes 121 share a single glass through hole 111 and are respectively electrically connected to the corresponding conductive portions 112 in the glass through hole 111. In other embodiments, the glass through hole 111 may be disposed at other positions, which may be reasonably determined based on actual conditions, with the connecting lines 113 routed according to the principle of proximity. Through the above configuration, the six anodes 121 share a single glass through hole 111, reducing the number of glass through holes 111 by five-sixths. The density of glass through holes 111 on the glass substrate 11 is also reduced by five-sixths, thereby significantly decreasing the number of through holes and their density, and thus improving the through hole yield rate and the strength of the glass substrate 11.

In some embodiments, the number of the conductive portions 112 in each glass through hole 111 on the glass substrate 11 may be different, which may be specifically determined based on the arrangement of the light-emitting units L and the positions of the glass through holes 111 to ensure that the anodes 121 of the light-emitting units L in corner regions can form electrical connections with the corresponding conductive portions 112 according to the principle of proximity, while ensuring that the number of the glass through holes 111 meets the requirements and that the layout of the connecting lines is as reasonable as possible, such that the path lengths of the connecting lines 113 are approximately the same and no excessively long lines exist, thereby ensuring the integrity of signal transmission and reducing voltage drop.

Continue to refer to FIG. 2, in the embodiment, an insulating layer 117 is arranged between the connecting lines 113 to prevent short circuits between the lines. Additionally, an insulating layer 117 is further arranged between the anode 121 and a non-corresponding connecting line 113 to ensure electrical insulation between the anode 121 and the non-corresponding connecting line 113, thereby preventing short circuits that could disrupt signal transmission.

Furthermore, a pixel definition layer 13 is arranged on a side of the insulating layer 117 away from the glass substrate 11. The pixel definition layer 13 defines multiple pixel openings through a patterning process, with each pixel opening corresponding to a light-emitting unit L. These pixel openings are overlapped with the anodes 121 in a direction perpendicular to the glass substrate 11, for exposing the anodes 121. The light-emitting structures 141 are disposed within the pixel openings and in contact with the anodes 121, while the cathode 15 is disposed on a side of the light-emitting structures 141 away from the glass substrate 11 and in contact with the light-emitting layers 14. Through the above configuration, the anode 121, the light-emitting structure 141, and the cathode 15 in each pixel opening forms a corresponding light-emitting unit L.

Referring to FIG. 7, FIG. 7 is a structural schematic view of a light-emitting substrate according to a third implementation of the present disclosure. In the embodiments, in the insulating limiting layer 115 within the glass through hole 111, the insulating limiting layer 115 is subjected to a nanoimprinting technology to define the electrode through holes 114 on a side close to the light-emitting unit L, and the conductive portions 112 are filled and arranged in the electrode through holes 114. On a side of the insulating limiting layer 115 away from the light-emitting unit L, connecting grooves 116 are defined by the nanoimprinting technology, and a bottom of each connecting groove 116 exposes a corresponding conductive portion 112. In this way, when the light-emitting substrate 10 and the drive substrate 20, the drive electrodes 23 on the drive substrate 20 can be aligned and embedded into the connecting grooves 116 to be connected to the conductive portions 112 and form an electrical connection. By arranging the connecting grooves 116, it is advantageous for the alignment and connecting of the drive electrodes 23 and the conductive portions 112, thereby improving alignment accuracy. Moreover, by embedding the drive electrodes 23 into the connecting grooves 116, the connecting stability between the light-emitting substrate 10 and the drive substrate 20 is improved, thereby preventing misalignment. In addition, it may further reduce the thickness of the display panel 100 and minimize the gap between the light-emitting substrate 10 and the drive substrate 20.

Referring to FIG. 8, FIG. 8 is a structural schematic view of a display panel according to some embodiments of the present disclosure. In the embodiments, a display panel 100 is provided, which includes a light-emitting substrate 10 and a drive substrate 20. The drive substrate 20 is aligned and connected with the light-emitting substrate 10, enabling the drive substrate 20 to drive the light-emitting substrate 10 to emit light, thereby displaying images.

The drive substrate 20 includes a silicon substrate 21, a drive circuit layer 22, a drive electrode layer, and an insulating protective layer 24, which are stacked in sequence. Specifically, in some embodiments, the silicon substrate 21 may be configured as a single crystal silicon substrate.

The drive circuit layer 22 includes multiple pixel drive circuit units (not shown), each of which includes a drive device. In some embodiments, a CMOS device may serve as the drive device to form the pixel drive circuit units, thereby driving the light-emitting units L in the light-emitting substrate 10 to emit light.

The drive electrode layer is electrically coupled to the drive circuit layer 22, and the drive electrode layer includes multiple drive electrodes 23, which are electrically connected to the pixel drive circuit units, such that drive signals are transmitted from the pixel drive circuit units to the drive electrodes 23 and then transmitted through the drive electrodes 23 to the light-emitting substrate 10. Specifically, the drive electrodes 23 include an anode drive electrode 231 and a cathode drive electrode 232. The cathode drive electrode 232 is disposed in an edge region of the drive electrode layer and is configured to be electrically coupled with the cathode 15 in the light-emitting substrate 10. The anode drive electrode 231 is configured to be electrically coupled with the anode 121 of the light-emitting unit L; the anode drive electrode 231 is disposed in a main region of the drive electrode layer and is arranged in correspondence with and facing the conductive portion 112 in the light-emitting substrate 10 to facilitate alignment and connecting between the drive substrate 20 and the conductive portion 112.

The insulating protective layer 24 is disposed on a side of the drive circuit layer 22 away from the silicon substrate 21 and includes defines through holes. The drive electrodes 23 pass through the insulating protective layer 24 to be electrically connected to the pixel drive circuit units, and a portion of each drive electrode 23 protrudes from a corresponding through hole to facilitate alignment and connecting with the light-emitting substrate 10. The insulating protective layer 24 may include an organic insulating layer and/or an inorganic insulating layer. The insulating protective layer 24 may specifically be configured as an inorganic insulating layer, and the material of the inorganic insulating layer may specifically be an inorganic insulating material such as silicon dioxide, silicon nitride, or silicon oxide.

The specific structure and function of the light-emitting substrate 10 are the same or similar to those described in the above embodiments and can achieve the same technical effects. For details, reference may be made to the description of the above embodiments, and the repetition is omitted herein. Specifically, the manufacturing method of the display panel 100 may be referred to the following description.

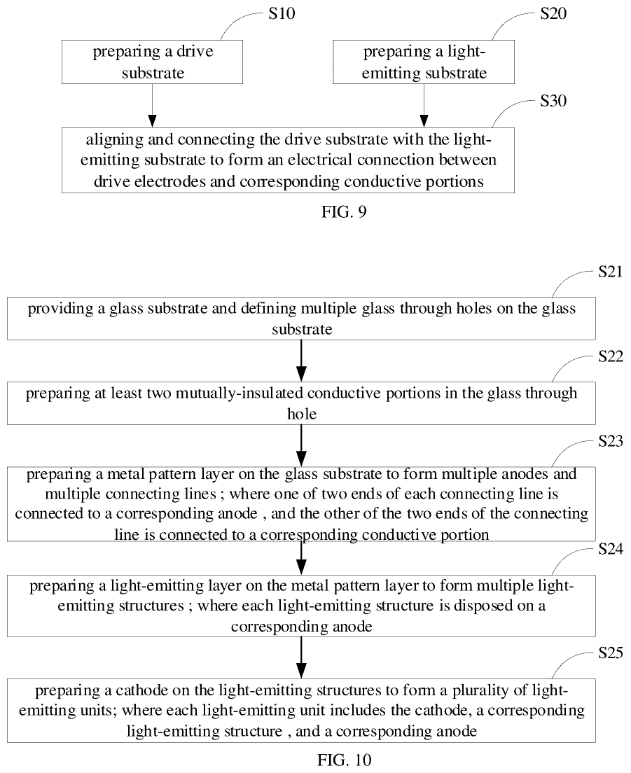

Referring to FIG. 9, FIG. 9 is a flowchart of a method for manufacturing a display panel according to some embodiments of the present disclosure. The present embodiments provide a method for manufacturing a display panel 100, which is configured to prepare the display panel 100 described in the above embodiments. The method includes operations at blocks illustrated herein. At block S10: preparing a drive substrate 20.
At block S20: preparing a light-emitting substrate 10.
At block S30: aligning and connecting the drive substrate 20 with the light-emitting substrate 10 to form an electrical connection between drive electrodes 23 and corresponding conductive portions 112.

The operations S10 and S20 are not sequential. That is, the light-emitting substrate 10 and the drive substrate 20 are manufactured separately, and the operations S10 and S20 may be performed according to production requirements without a specific sequence. The drive substrate 20 includes a drive circuit layer 22 and drive electrodes 23 disposed on a side of the drive circuit layer 22. The specific structure and function of the drive substrate 20 and the light-emitting substrate 10 are the same or similar to those described in the above embodiments and can achieve the same technical effects. For details, reference may be made to the relevant descriptions above.

Referring to FIG. 10, FIG. 10 is a flowchart of a method for manufacturing a light-emitting substrate according to some embodiments of the present disclosure. The preparing the light-emitting substrate 10 in operation S10 specifically include the following.
At block S21: providing a glass substrate 11 and defining multiple glass through holes 111 on the glass substrate 11.
At block S22: preparing at least two mutually-insulated conductive portions 112 in the glass through hole 111.
At block S23: preparing a metal pattern layer on the glass substrate 11 to form multiple anodes 121 and multiple connecting lines 113; where one of two ends of each connecting line 113 is connected to a corresponding anode 121, and the other of the two ends of the connecting line 113 is connected to a corresponding conductive portion 112.
At block S24: preparing a light-emitting layer 14 on the metal pattern layer to form multiple light-emitting structures 141; where each light-emitting structure 141 is disposed on a corresponding anode 121.
At block S25: preparing a cathode 15 on the light-emitting structures 141 to form a plurality of light-emitting units L; where each light-emitting unit L includes the cathode 15, a corresponding light-emitting structure 141, and a corresponding anode 121.

Specifically, in the operation S21, hole opening may be performed on the glass substrate 11 using laser ablation. Specifically, a laser may be applied to perform laser ablation at positions where holes are required, forming corresponding modified regions in the areas of the glass substrate 11 where holes are required. Then, the modified regions are etched using an etching solution to define the glass through holes 111.

In the operation S22, an insulating material may be filled into the glass through hole 111, and at least two electrode through holes 114 may be defined in the insulating material. A conductive material is then filled into the electrode through holes 114 to form the at least two conductive portions 112. In the operation S23, the connecting line 113 and the anode 121 may be fabricated separately, i.e., by patterning two metal layers separately.

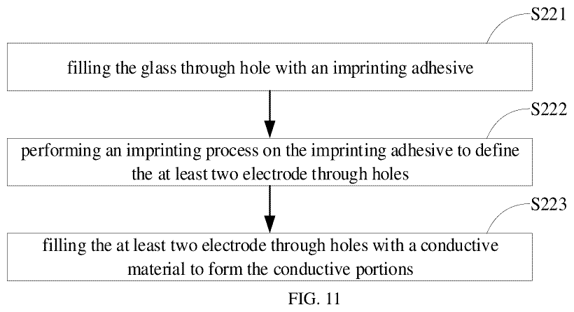

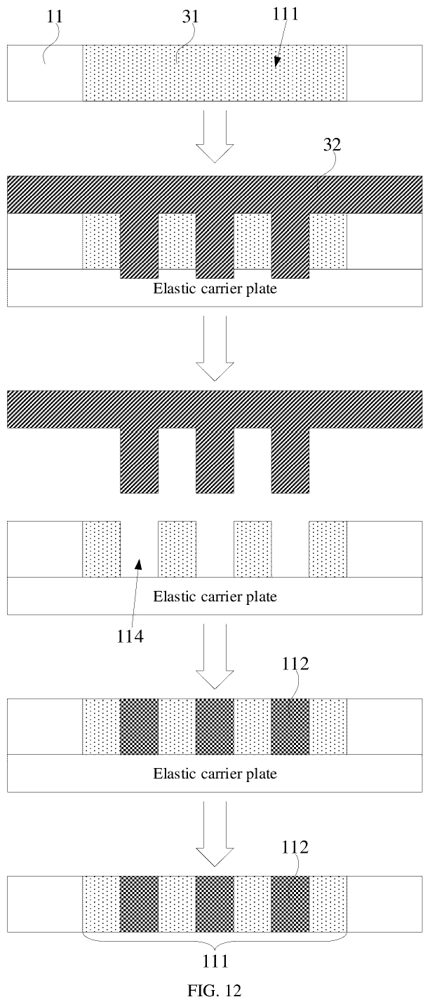

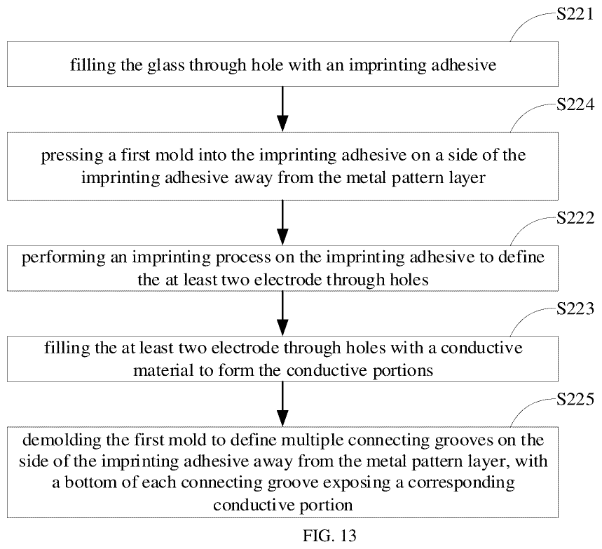

Referring to FIGS. 11 and 12, FIG. 11 is a flowchart of operation S22 in FIG. 10 according to some embodiments of the present disclosure, and FIG. 12 is a schematic view of the process corresponding to FIG. 11. The preparing the at least two mutually-insulated conductive portions 112 in the glass through holes 111 in the operation S22 may specifically include the following.
At block S221: filling the glass through hole 111 with an imprinting adhesive 31.
At block S222: performing an imprinting process on the imprinting adhesive 31 to define the at least two electrode through holes 114.
At block S223: filling the at least two electrode through holes 114 with a conductive material to form the conductive portions 112.

The material of the imprinting adhesive 31 may specifically be an organic insulating plastic material, such as common polyvinyl chloride (PVC), polypropylene (PP), and other organic insulating materials. In the operation S222, the imprinting process is performed on the imprinting adhesive 31 using a second mold 32. After the imprinting is completed, a demolding process is performed to define the electrode through holes 114 matching the mold pattern on the imprinting adhesive 31, that is, the imprinting adhesive 31 is used to form the insulating limiting layer 115 described above through the imprinting process. In the operation S223, the conductive material is filled into the electrode through holes 114 to form the conductive portions 112 within the electrode through holes 114. The conductive material may specifically be metallic materials such as silver (Ag), copper (Cu), or aluminum (Al), or may be other conductive materials, without limitation herein.

In the embodiments, the use of nanoimprinting technology to form the conductive portion 112 helps improve the yield of the electrode through holes 114. The nanoimprinting technology involves the transfer of patterns through contact imprinting, which is equivalent to the exposure and development processes in optical exposure technology. The structures are then transferred to other materials using an etching transfer process. The nanoimprinting technology overcomes the resolution limitations caused by light diffraction in exposure technology, demonstrating unique advantages such as ultra-high resolution, high efficiency, low cost, and suitability for industrial production. The latest nanoimprint lithography (NIL) technology has achieved a patterning accuracy of 5 nm for electrical line widths. Currently, common nanoimprinting technologies include thermal imprinting, UV imprinting, and mold imprinting. In the illustrated embodiments of the present disclosure, mold imprinting technology is adopted.

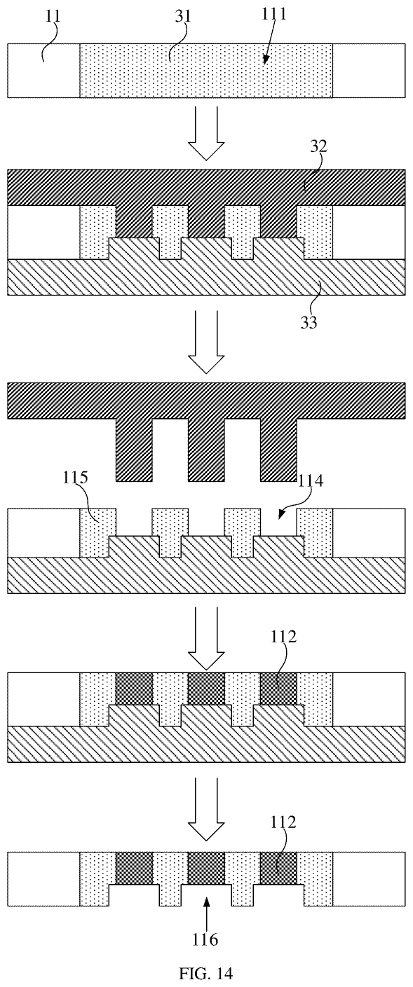

Referring to FIGS. 13 and 14, FIG. 13 is a flowchart of operation S22 in FIG. 10 according to other embodiments of the present disclosure, and FIG. 14 is a schematic view of the process corresponding to FIG. 13. In the embodiments, the following operation is included before S222.
At block S224: pressing a first mold 33 into the imprinting adhesive 31 on a side of the imprinting adhesive 31 away from the metal pattern layer.

After S223, the following operation is further included.
At block S225: demolding the first mold 33 to define multiple connecting grooves 116 on the side of the imprinting adhesive 31 away from the metal pattern layer, with a bottom of each connecting groove 116 exposing a corresponding conductive portion 112.

In the embodiments, not only are the conductive portions 112 formed in the glass through hole 111, but the connecting grooves 116 are also defined on the imprinting adhesive 31 on a side of the conductive portion 112 away from the light-emitting unit L. Specifically, in the embodiments, when performing the imprinting process on the imprinting adhesive 31, two molds are used, namely the first mold 33 and the second mold 32. The first mold 33 is configured to press and define the connecting grooves 116, and the second mold 32 is configured to press and define the electrode through holes 114.

After the imprinting process is completed, the second mold 32 may be demolded first, followed by the operation S223 to form the conductive portions 112 in the electrode through holes 114. After the conductive portions 112 are formed, the operation S225 is performed to demold the first mold 33, to define the connecting grooves 116 on the side of the conductive portion 112 away from the light-emitting unit L, such that the bottom of the connecting groove 116 exposes the conductive portion 112, thereby ensuring that, after the light-emitting substrate 10 and the drive substrate 20 are aligned and connected, the drive electrodes 23 can form reliable electrical connections with the corresponding conductive portions 112.

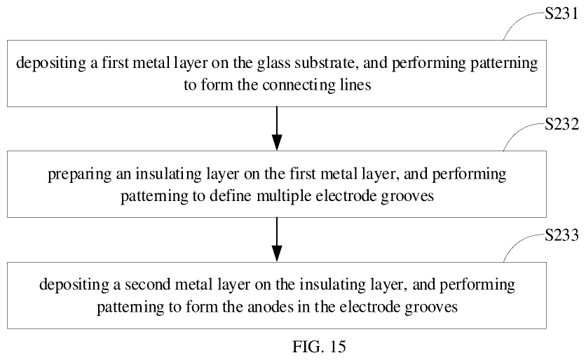

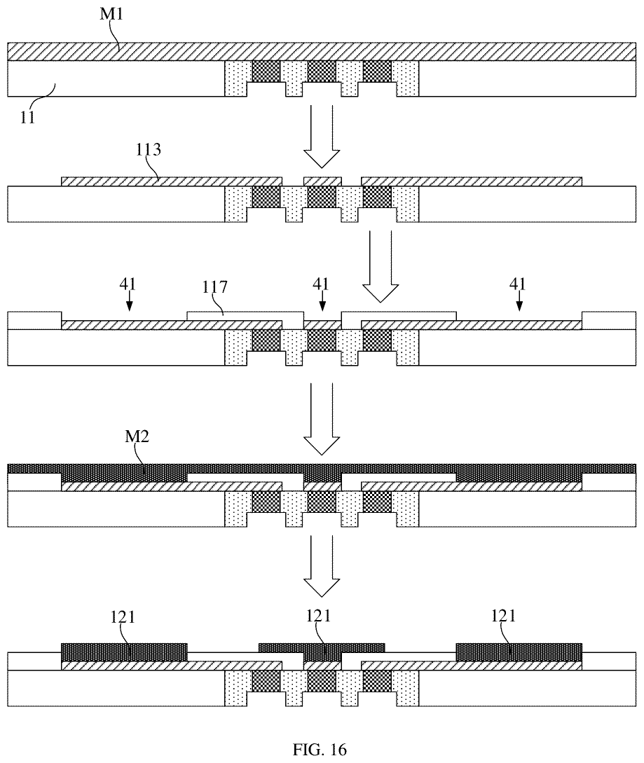

Referring to FIGS. 15 and 16, FIG. 15 is a flowchart of operation S23 in FIG. 10 according to some embodiments of the present disclosure, and FIG. 16 is a schematic view of the process corresponding to FIG. 15. In the embodiments, the operation S23 specifically includes the following.
At block S231: depositing a first metal layer M1 on the glass substrate 11, and performing patterning to form the connecting lines 113.
At block S232: preparing an insulating layer 117 on the first metal layer M1, and performing patterning to define multiple electrode grooves 41.
At block S233: depositing a second metal layer M2 on the insulating layer 117, and performing patterning to form the anodes 121 in the electrode grooves 41.

In the embodiments, the connecting lines 113 are first formed on the glass substrate 11. Specifically, the first metal layer M1 is first deposited on the glass substrate 11 and patterned, for example by photolithography or similar processes, to form the connecting lines 113, with an end of each connecting line 113 connected to a corresponding conductive portion 112.

Then, the insulating layer 117 is prepared on the first metal layer M1 and patterned to define the multiple electrode grooves 41, leaving the regions for the anodes 121 open. Subsequently, the second metal layer M2 is deposited on the insulating layer 117 and patterned to form the anodes 121 in the electrode grooves 41.

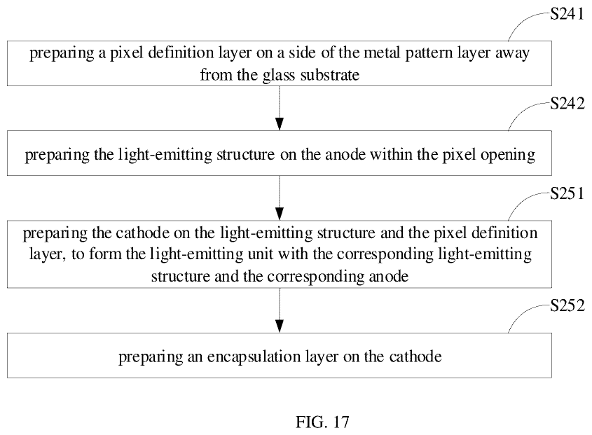

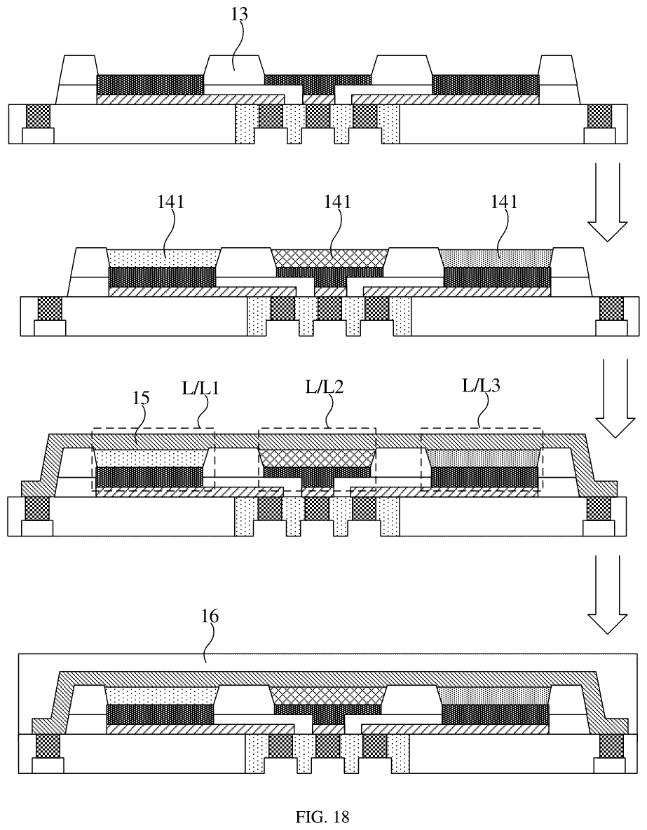

Referring to FIGS. 17 and 18, FIG. 17 is a flowchart of operations S24 and S25 in FIG. 10 according to some embodiments of the present disclosure, and FIG. 18 is a schematic view of the process corresponding to FIG. 17. In the embodiments, the operation S24 specifically includes the following.
At block S241: preparing a pixel definition layer 13 on a side of the metal pattern layer away from the glass substrate 11.
At block S242: preparing the light-emitting structure 141 on the anode 121 within the pixel opening.

The operation S25 specifically includes the following.
At block S251: preparing the cathode 15 on the light-emitting structure 141 and the pixel definition layer 13, to form the light-emitting unit L with the corresponding light-emitting structure 141 and the corresponding anode 121.
At block S252: preparing an encapsulation layer 16 on the cathode 15.

Specifically, the cathode 15 extends to an edge position of the glass substrate 11 and is electrically connected to the signal lines on the drive substrate 20 via the conductive portions 112 in the glass through holes 111. It should be noted that only one conductive portion 112 is required to be provided in the glass through hole 111 corresponding to the cathode 15. That is, the glass through hole 111 corresponding to the cathode 15 may be directly filled with conductive material to form the single conductive portion 112.

Furthermore, the operation S30 specifically includes the following.
At block S31: applying a conductive adhesive on the drive electrode 23 or within the connecting groove 116.
At block S32: aligning the drive substrate 20 with the light-emitting substrate 10, for aligning and embedding the drive electrodes 23 in the connecting grooves 116.
At block S32: connecting the drive substrate 20 and the light-emitting substrate 10 to form an electrical connection between the drive electrode 23 and the conductive portion 112.

Specifically, the structure of the display panel 100 formed by connecting the light-emitting substrate 10 and the drive substrate 20 using the above connecting method is the same as that of the display panel 100 shown in FIG. 8. This alignment method may improve alignment accuracy; additionally, by embedding the drive electrode 23 into the connecting groove 116, the connecting stability between the light-emitting substrate 10 and the drive substrate 20 is enhanced, thereby prevent misalignment; further, it may reduce the thickness of the display panel 100 and minimize the gap between the light-emitting substrate 10 and the drive substrate 20.

In the embodiments of the present disclosure, a display device (not shown) is further provided, which includes the display panel 100 described in the above embodiments. The display panel 100 may improve the connection reliability and signal transmission effectiveness and integrity between the light-emitting substrate 10 and the drive substrate 20, and further enhance the product yield rate.

The beneficial effects of the present disclosure: Different from the related art, the present disclosure provides a light-emitting substrate, a display panel, and a method for manufacturing the same. The light-emitting substrate includes a glass substrate, a metal pattern layer, a light-emitting layer, and a cathode. The metal pattern layer includes multiple anodes, which, together with the light-emitting layer and the cathode, form light-emitting units. The light-emitting units are arranged in an array on the glass substrate, thereby enabling the formation of light-emitting units on the glass substrate without the need to directly form them on the drive substrate, which may avoid the reduction of product yield caused by the issue of damaging the pixel drive circuit when light-emitting units are directly formed on the drive substrate. Additionally, by providing conductive portions in the glass through holes and electrically connecting the conductive portions to the corresponding anodes via connecting lines on the metal pattern layer, after the light-emitting substrate and the drive substrate are aligned and connected, the drive circuits in the drive substrate can be electrically connected to the light-emitting units via the conductive portions and the connecting lines, thereby driving the light-emitting units to emit light and display corresponding images. Furthermore, by configuring at least two mutually insulated conductive regions in each glass through hole and forming the connecting lines on the metal pattern layer, each conductive region in the glass through hole can be electrically connected to the corresponding anode via the connecting line. This means that a single glass through hole can correspond to at least two anodes, and multiple signals can be transmitted within a single glass through hole, which may effectively reduce the number of glass through holes on the glass substrate, thereby lowering the density of glass through holes on the glass substrate, so as to enhance the strength of the glass substrate and improve the through-hole yield rate. Additionally, by configuring at least two conductive portions within each glass through hole, not only is the through-hole density of the glass substrate reduced, but this also facilitates ultra-high-resolution design, enabling the achievement of ultra-high-resolution display panels and enhancing image display quality.

The above is merely some embodiments of the present disclosure and does not limit the scope of the present disclosure. Any equivalent structures or equivalent process changes made based on the content of the specification and drawings of the present disclosure, or any direct or indirect application in other related technical fields, are similarly included within the scope of the present disclosure.

1. A light-emitting substrate, comprising:
a glass substrate, defining a plurality of first glass through holes; wherein at least two conductive portions are arranged in each first glass through hole, and the at least two conductive portions in the first glass through hole are insulated from each other;
a metal pattern layer, disposed on the glass substrate and comprising a plurality of anodes and a plurality of connecting lines; wherein each conductive portion is electrically connected to a corresponding anode via a corresponding connecting line;
a light-emitting layer, comprising a plurality of light-emitting structures; wherein each light-emitting structure is disposed on a corresponding anode; and
a cathode, disposed on a side of the plurality of light-emitting structures away from the glass substrate; wherein the cathode, the plurality of light-emitting structures, and the plurality of anodes together form a plurality of light-emitting units.

2. The light-emitting substrate according to claim 1, wherein each first glass through hole is filled with an insulating limiting layer, and the insulating limiting layer defines at least two electrode through holes; the at least two conductive portions in the first glass through hole are filled and disposed within the at least two electrode through holes.

3. The light-emitting substrate according to claim 2, wherein a diameter of each electrode through hole is greater than 0.2 μm, and a spacing between each adjacent two of the at least two electrode through holes is equal to or greater than 0.2 μm.

4. The light-emitting substrate according to claim 1, wherein each first glass through hole is disposed between corresponding adjacent light-emitting units of the plurality of light-emitting units; the at least two conductive portions in the first glass through hole are electrically connected to the anodes of the corresponding adjacent light-emitting units in a one-to-one correspondence.

5. The light-emitting substrate according to claim 4, wherein each first glass through hole is disposed between corresponding adjacent two light-emitting units of the plurality of light-emitting units, and a number of the at least two conductive portions arranged in the first glass through hole is two; the two conductive portions arranged in the first glass through hole are electrically connected to the anodes of the corresponding adjacent two light-emitting units via corresponding two connecting lines.

6. The light-emitting substrate according to claim 4, wherein each first glass through hole is disposed below one of corresponding adjacent two light-emitting units of the plurality of light-emitting units, and a number of the at least two conductive portions arranged in the first glass through hole is two; the anode of the one of the corresponding adjacent two light-emitting units is directly electrically connected to a corresponding one of the two conductive portions arranged in the first glass through hole, and the anode of the other of the corresponding adjacent two light-emitting units is electrically connected to the other of the two conductive portions arranged in the first glass through hole via a corresponding connecting line.

7. The light-emitting substrate according to claim 4, wherein each first glass through hole is disposed at an intersection of corresponding adjacent three light-emitting units of the plurality of light-emitting units, and a number of the at least two conductive portions arranged in the first glass through hole is three; the three conductive portions arranged in the first glass through hole are electrically connected to the anodes of the corresponding adjacent three light-emitting units via corresponding three connecting lines.

8. The light-emitting substrate according to claim 4, wherein each first glass through hole is disposed below one of corresponding adjacent three light-emitting units of the plurality of light-emitting units, and a number of the at least two conductive portions arranged in the first glass through hole is three; the anode of the one of the corresponding adjacent three light-emitting units is directly electrically connected to a corresponding one of the three conductive portions arranged in the first glass through hole, and the anodes of the other two of the corresponding adjacent three light-emitting units are electrically connected to the other two of the three conductive portions arranged in the first glass through hole via corresponding two connecting lines.

9. The light-emitting substrate according to claim 4, wherein each first glass through hole is disposed at an intersection of corresponding adjacent four light-emitting units of the plurality of light-emitting units, and a number of the at least two conductive portions arranged in the first glass through hole is six; four of the six conductive portions arranged in the first glass through hole are electrically connected to the anodes of the corresponding adjacent four light-emitting units via corresponding four connecting lines; the other two of the six conductive portions arranged in the first glass through hole are electrically connected to the anodes of another two light-emitting units of the plurality of light-emitting units; the another two light-emitting units are adjacent to the corresponding adjacent four light-emitting units.

10. The light-emitting substrate according to claim 1, wherein a number of the at least two conductive portions arranged in each first glass through hole is not the same.

11. The light-emitting substrate according to claim 1, wherein at least one of the following is satisfied:
an insulating layer is arranged between adjacent two of the plurality of connecting lines;
an insulating layer is arranged between each anode and a non-corresponding connecting line.

12. The light-emitting substrate according to claim 2, wherein connecting grooves are defined on a side of the insulating limiting layer away from the light-emitting layer, and a bottom of each connecting groove exposes a corresponding conductive portion.

13. The light-emitting substrate according to claim 1, wherein the glass substrate further defines a second glass through hole, and the second glass through hole is arranged with a single conductive portion; the single conductive portion is electrically connected to the cathode.

14. A display panel, comprising:
a light-emitting substrate; and
a drive substrate, comprising a drive circuit layer and drive electrodes arranged on a side of the drive circuit layer;
wherein the light-emitting substrate comprises:
a glass substrate, defining a plurality of first glass through holes; wherein at least two conductive portions are arranged in each first glass through hole, and the at least two conductive portions in the first glass through hole are insulated from each other;
a metal pattern layer, disposed on the glass substrate and comprising a plurality of anodes and a plurality of connecting lines; wherein each conductive portion is electrically connected to a corresponding anode via a corresponding connecting line;
a light-emitting layer, comprising a plurality of light-emitting structures; wherein each light-emitting structure is disposed on a corresponding anode; and
a cathode, disposed on a side of the plurality of light-emitting structures away from the glass substrate; wherein the cathode, the plurality of light-emitting structures, and the plurality of anodes together form a plurality of light-emitting units;
wherein the drive substrate is aligned with the light-emitting substrate, and the drive electrodes are aligned and connected with the at least two conductive portions in each first glass through hole in a one-to-one correspondence.

15. The display panel according to claim 14, wherein each first glass through hole is filled with an insulating limiting layer, and the insulating limiting layer defines at least two electrode through holes; the at least two conductive portions in the first glass through hole are filled and disposed within the at least two electrode through holes.

16. A method for manufacturing a display panel, comprising:
preparing a drive substrate; wherein the drive substrate comprises a drive circuit layer and drive electrodes arranged on a side of the drive circuit layer;
preparing a light-emitting substrate, comprising:
providing a glass substrate, and defining a plurality of glass through holes on the glass substrate;
preparing at least two conductive portions in each glass through hole, wherein the at least two conductive portions in the glass through hole are insulated from each other;
preparing a metal pattern layer on the glass substrate to form a plurality of anodes and a plurality of connecting lines; wherein one of two ends of each connecting line is connected to a corresponding anode, and the other of the two ends of the connecting line is connected to a corresponding conductive portion;
preparing a light-emitting layer on the metal pattern layer to form a plurality of light-emitting structures; wherein each light-emitting structure is disposed on a corresponding anode; and
preparing a cathode on the plurality of light-emitting structures to form a plurality of light-emitting units; wherein each light-emitting unit comprises the cathode, a corresponding light-emitting structure, and a corresponding anode; and
aligning and connecting the drive substrate with the light-emitting substrate to form an electrical connection between each drive electrode and a corresponding conductive portion.

17. The manufacturing method according to claim 16, wherein the preparing at least two conductive portions in each glass through hole comprises:
filling the glass through hole with an imprinting adhesive;
performing an imprinting process on the imprinting adhesive to define at least two electrode through holes; and
filling the at least two electrode through holes with a conductive material to form the at least two conductive portions.

18. The manufacturing method according to claim 17, before the performing an imprinting process on the imprinting adhesive to define at least two electrode through holes, further comprising:
pressing a first mold into the imprinting adhesive on a side of the imprinting adhesive away from the metal pattern layer; wherein the first mold includes a protrusion aligned with each electrode through hole, and a height of the protrusion is less than a thickness of the glass substrate;
wherein after the filling the at least two electrode through holes with a conductive material to form the at least two conductive portions, the manufacturing method further comprises:
demolding the first mold to define at least two connecting grooves on the side of the imprinting adhesive away from the metal pattern layer, with a bottom of each connecting groove exposing a corresponding conductive portion.

19. The manufacturing method according to claim 18, wherein the aligning and connecting the drive substrate with the light-emitting substrate to form an electrical connection between each drive electrode and a corresponding conductive portion comprises:
applying a conductive adhesive on the drive electrode or within each connecting groove;
aligning the drive substrate with the light-emitting substrate, for aligning and embedding each drive electrode in a corresponding connecting groove; and
connecting the drive substrate and the light-emitting substrate to form the electrical connection between each drive electrode and a corresponding conductive portion.

20. The manufacturing method according to claim 16, wherein the preparing a metal pattern layer on the glass substrate to form a plurality of anodes and a plurality of connecting lines comprises:
depositing a first metal layer on the glass substrate, and performing patterning to form the plurality of connecting lines;
preparing an insulating layer on the first metal layer, and performing patterning to define a plurality of electrode grooves; and
depositing a second metal layer on the insulating layer, and performing patterning to form the plurality of anodes in the plurality of electrode grooves.
